(19) United States
(12) Patent Application Publication
(10) Pub. No.: US 2016/0037620 A1
(43) Pub. Date: Feb. 4, 2016

(54) PRINTED CIRCUIT BOARD AND MANUFACTURING METHOD THEREOF

(71) Applicant: SAMSUNG ELECTRO-MECHANICS CO., LTD., Suwon-Si (KR)

(72) Inventors: Myung Sam KANG, Suwon-Si (KR); Young Gwan KO, Suwon-Si (KR); Tae Hong MIN, Suwon-Si (KR); Jung Han LEE, Suwon-Si (KR)

(21) Appl. No.: 14/668,804

(22) Filed: Mar. 25, 2015

(30) Foreign Application Priority Data
Aug. 1, 2014 (KR) 10-2014-0099049

(51) Int. Cl. H05K 1/02; H05K 3/42; H05K 3/00; H05K 3/32; H05K 1/11; H05K 1/18

(52) U.S. Cl. CPC H05K 1/021; H05K 1/0206; H05K 1/0298; H05K 1/115; H05K 1/186; H05K 3/0044; H05K 3/0094; H05K 3/32; H05K 3/429; H05K 2201/09545

(57) ABSTRACT

There is provided a printed circuit board including: a core layer having a cavity formed therein; a heat radiation body included in the cavity; an insulating layer provided on an upper surface and a lower surface of the core layer; and a heat dissipating via penetrating through the insulating layer to be in contact with the heat radiation body and dissipating heat externally, wherein the heat radiation body includes an insulating plate, a first metal block formed on an upper surface of the insulating plate, and a second metal block formed on a lower surface of the insulating plate.

### CROSS-REFERENCE TO RELATED APPLICATION

This application claims the priority and benefit of Korean Patent Application No. 10-2014-0099049 filed on Aug. 1, 2014, with the Korean Intellectual Property Office, the disclosure of which is incorporated herein by reference.

### BACKGROUND

The present disclosure relates to a printed circuit board and a manufacturing method thereof.

As an electronic device package such as a multi-chip package (MCP) in which a plurality of semiconductor chips are stacked and mounted on a single substrate, or a package on package (POP) in which a plurality of substrates having a plurality of semiconductor chips mounted thereon are stacked, has been miniaturized and increased in complexity, a printed circuit board for an electronic device package is required to have improved heat dissipating characteristics.

### RELATED ART DOCUMENT

(Patent Document 1) Korean Patent Laid-Open Publication No. 2014-0021910

### SUMMARY

An aspect of the present disclosure may provide a printed circuit board having improved heat dissipating characteristics and a manufacturing method thereof.

According to an aspect of the present disclosure, a printed circuit board may include: a core layer having a cavity formed therein; a heat radiation body included in the cavity; an insulating layer formed on an upper surface and a lower surface of the core layer; and a heat dissipating via penetrating through the insulating layer to be in contact with the heat radiation body and dissipating heat externally, wherein the heat radiation body is formed as a multilayer structure including an insulating plate, a first metal block formed on an upper surface of the insulating plate, and a second metal block formed on a lower surface of the insulating plate.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view showing a structure of a printed circuit board according to an exemplary embodiment of the present disclosure;

FIG. 2 is a perspective view of part ‘A’ of FIG. 1;

FIG. 3 is an enlarged view of part ‘A’ of FIG. 1;

FIGS. 4 through 6 are perspective views showing a heat radiation body having a multilayer structure according to another exemplary embodiment of the present disclosure; and

FIGS. 7 through 14 are views sequentially illustrating a manufacturing method of a printed circuit board according to an exemplary embodiment of the present disclosure

### DETAILED DESCRIPTION

Exemplary embodiments of the present disclosure will now be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

Printed Circuit Board

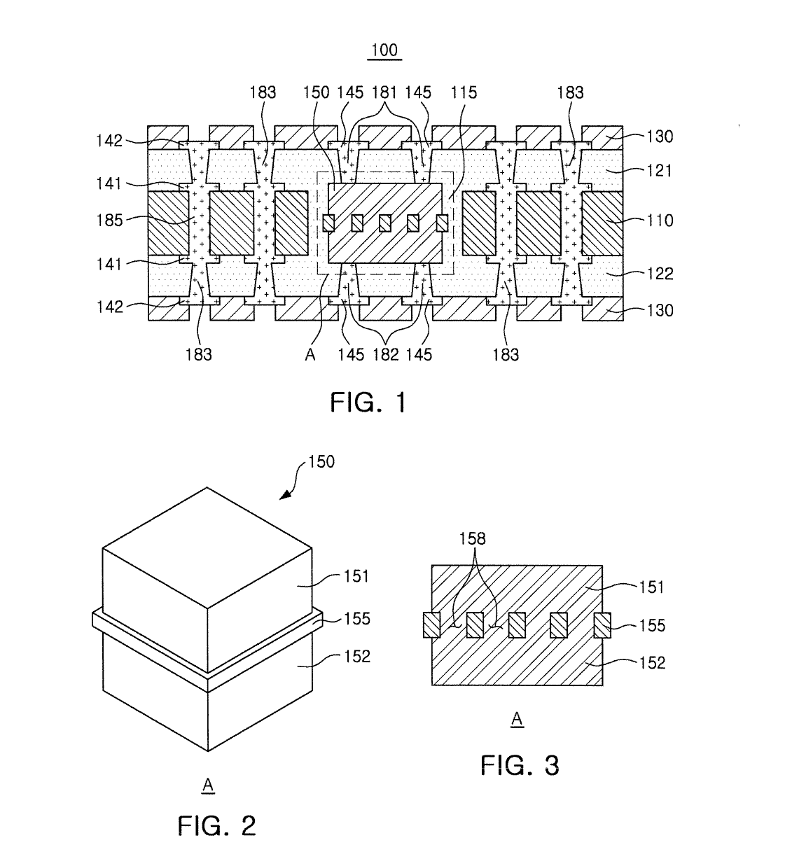

FIG. 1 is a cross-sectional view showing a structure of a printed circuit board according to an exemplary embodiment of the present disclosure.

Referring to FIG. 1, a printed circuit board 100 according to an exemplary embodiment of the present disclosure may include a core layer 110 having a cavity 115 formed therein, a heat radiation body 150 included in the cavity 115, insulating layers 121 and 122 formed on an upper surface and a lower surface of the core layer 110, and heat dissipating vias 181 and 182 formed to be in contact with the heat radiation body 150 and dissipating heat externally.

The heat radiation body 150 according to an exemplary embodiment of the present disclosure may be formed in a multilayer structure including an insulating plate, a first metal block formed on an upper surface of the insulating plate, and a second metal block formed on a lower surface of the insulating plate.

Since an exemplary embodiment of the present disclosure has a structure in which a volume and a cross-section area of a heat dissipating passage are significantly increased by inserting the heat radiation body 150, as compared to a structure according to the related art in which heat is dissipated through a general via, heat dispersion characteristics may be improved and heat from mounted electronic devices may be efficiently dissipated.

The core layer 110 may have a structure having inner layer circuits 141 formed on an upper surface and a lower surface of the insulating layer and the inner layer circuits 141 formed on the upper surface and the lower surface of the insulating layer may be electrically connected to each other through a core via 185.

The core layer 110 may be provided with the cavity 115 penetrating through the core layer 110 so that the heat radiation body 150 may be inserted thereinto. The cavity 115 may be formed by a punch or a blade.

The heat radiation body 150 may be included in the cavity 115 and may be buried in the cavity 115 by the insulating layers 121 and 122 formed on the upper surface and the lower surface of the core layer 110.

Since the heat radiation body 150 has a size equal to or larger than that of the electronic device to be mounted on the printed circuit board 100, heat may be more efficiently dissipated externally as compared to the case in which heat of the electronic device is dissipated through the general via according to the related art.

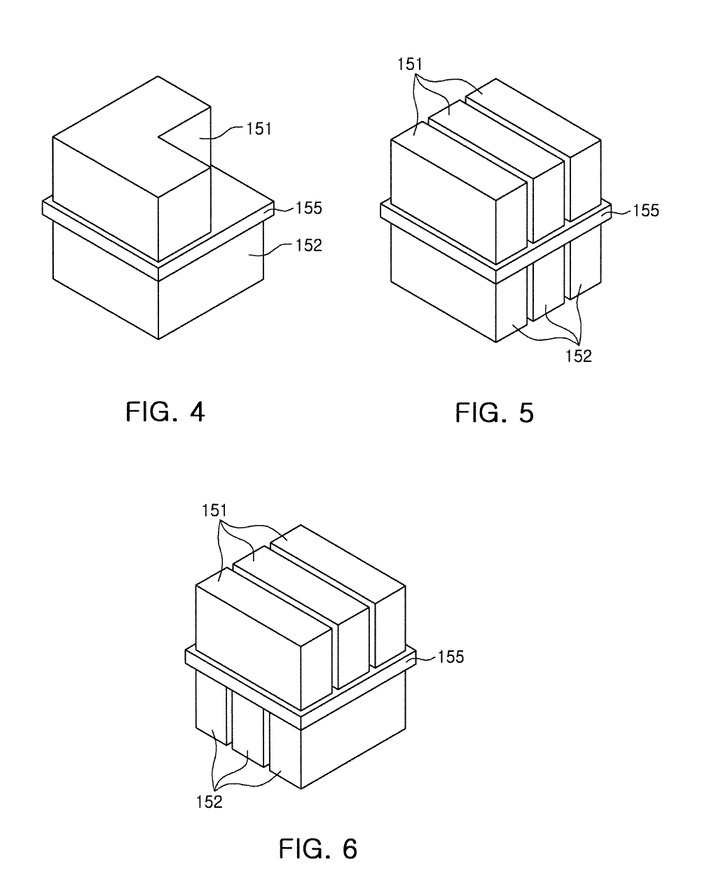

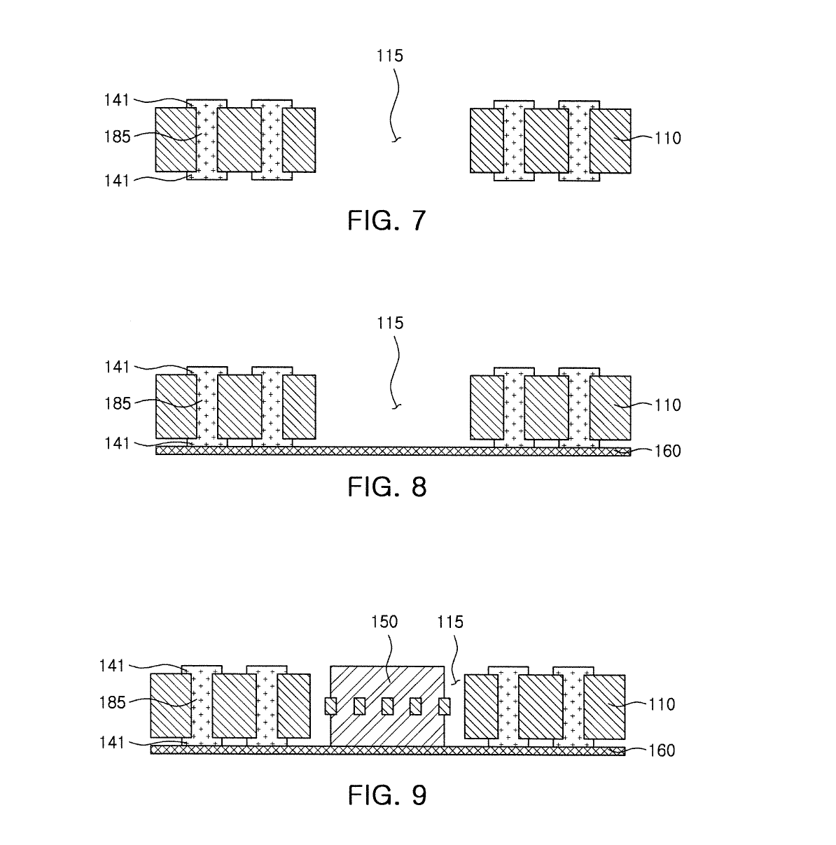

FIG. 2 is a perspective view of part ‘A’ of FIG. 1 and FIG. 3 is an enlarged view of part ‘A’ of FIG. 1.

Referring to FIG. 2, the heat radiation body 150 may include an insulating plate 155, a first metal block 151 formed on an upper surface of the insulating plate 155, and a second metal block 152 formed on a lower surface of the insulating plate 155.

The insulating plate 155 may include a resin insulating material. As the resin insulating material, a thermosetting resin such as an epoxy resin, a thermoplastic resin such as polyimide, or the like may be used, but the resin insulating material is not necessarily limited thereto.

The first metal block 151 or the second metal block 152 may have a rectangular parallelepiped shape, but is not necessarily limited thereto. For example, as long as it may secure a volume and a cross-section area sufficient to improve heat dispersion characteristics, any block shape may be used.

Referring to FIG. 3, the heat radiation body 150 may include an inner via 158 penetrating through the insulating plate 155.

The first metal block 151 and the second metal block 152 may be connected to each other through the inner via 158.

The first metal block 151, the second metal block 152, and the inner via 158 may be formed of at least one selected from a group consisting of copper (Cu), aluminum (Al), and invar.

Since the heat radiation body 150 having the multilayer structure according to an exemplary embodiment of the present disclosure has an increased volume and cross-section area of the heat dissipating passage, heat dispersion characteristics may be improved and heat of the mounted electronic device may be efficiently dissipated.

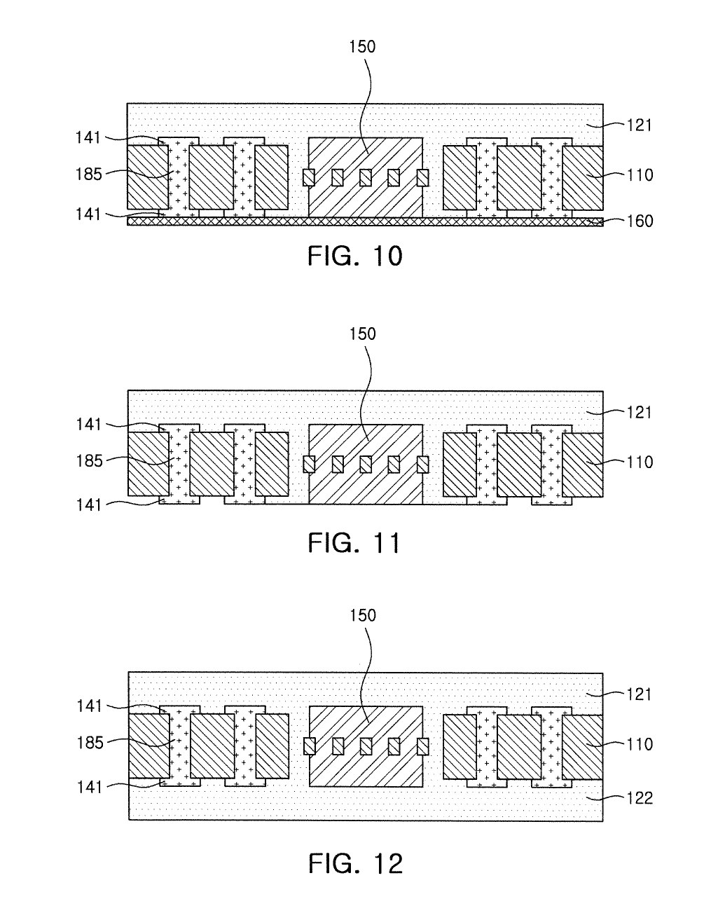

FIGS. 4 through 6 are perspective views showing a heat radiation body having a multilayer structure according to another exemplary embodiment of the present disclosure.

Referring to FIG. 4, the heat radiation body 150 according to another exemplary embodiment of the present disclosure has the first metal block 151 and the second metal block 152 that have shapes different from each other.

FIG. 4 illustrates the case in which the first metal block 151 has a shape of ‘ [symbol] ’ and the second metal block 152 has a rectangular parallelepiped shape, but the present disclosure is not limited thereto, and the heat radiation body 150 according to an exemplary embodiment of the present disclosure may show a structure in which the first metal block 151 and the second metal block 152 have different shapes.

The first metal block 151 and the second metal block 152 having the shapes different from each other may be connected to each other through an inner via (not shown) formed so as to penetrate through the insulating plate 155.

Referring to FIGS. 5 and 6, the heat radiation body 150 according to an exemplary embodiment of the present disclosure has the first metal block 151 or the second metal block 152 that includes a plurality of metal blocks.

The metal blocks of the first metal block 151 and the second metal block 152 may be disposed on positions corresponding to each other as shown in FIG. 5 and the metal blocks of the first metal block 151 and the second metal block 152 may be disposed not to correspond to each other as shown in FIG. 6, but are not particularly limited.

Although FIGS. 5 and 6 show the structure in which the metal blocks of the first metal block 151 and the second metal block 152 are each formed of three metal blocks having the same shape, the present disclosure is not limited thereto. For example, the metal blocks of the first metal block 151 and the second metal block 152 may be each formed of two or four or more metal blocks and the number and shapes of metal blocks included in the metal blocks of the first metal block 151 and the second metal block 152 may be different from each other.

The plurality of metal blocks included in the first metal block 151 and the second metal block 152 may be each connected through the inner via (not shown) formed so as to penetrate through the insulating plate 155.

Meanwhile, although the heat radiation body 150 having the multilayer structure is shown as a structure of the two layers, the structure of the heat radiation body 150 is not limited thereto. As long as the heat radiation body 150 is formed within a range which may be utilized by those skilled in the art, it may be formed in a structure of three or more layers including two or more insulating plates 155.

The insulating layers 121 and 122 may be formed on the upper surface and the lower surface of the core layer 110 into which the heat radiation body 150 is inserted.

By forming the insulating layer 121 on the upper surface of the core layer 110 into which the heat radiation body 150 is inserted, a space between the cavity 115 and the heat radiation body 150 is filled, whereby the heat radiation body 115 may be fixed to the cavity 115.

As the insulating layers 121 and 122, a resin insulating layer may be used. As materials of the resin insulating layer, a thermosetting resin such as an epoxy resin, a thermoplastic resin such as polyimide, a resin having a reinforcement material such as glass fiber or inorganic filler impregnated in them, for example, a prepreg may be used. However, the materials of the resin insulating layer are not particularly limited thereto.

The insulating layers 121 and 122 may have outer layer circuits 142 formed on surfaces thereof, and the inner layer circuits 141 and the outer layer circuits 142 of the core layer 110 may be electrically connected to each other through signal via 183 penetrating through the insulating layers 121 and 122.

Meanwhile, heat dissipating vias 181 and 182 may be formed so as to penetrate through the insulating layers 121 and 122 and be in contact with the heat radiation body 150 and may dissipate heat externally. The heat dissipating vias 181 and 182 may have heat dissipating pad 145 formed thereon.

The heat dissipating vias 181 and 182 may be formed on both upper and lower sides of the heat radiation body 150.

For example, heat generated from the electronic device mounted on the upper side of the heat radiation body 150 may be transferred to the heat radiation body 150 by the heat dissipating via 181 of the upper side of the heat radiation body 150 and may be transferred to the heat dissipating via 182 of the lower side of the heat radiation body 150, so as to be dissipated externally.

Meanwhile, a solder resist 130 may be disposed on a surface of the printed circuit board so as to expose the outer layer circuit 142 and the heat dissipating pad 145.

Method of Manufacturing Printed Circuit Board

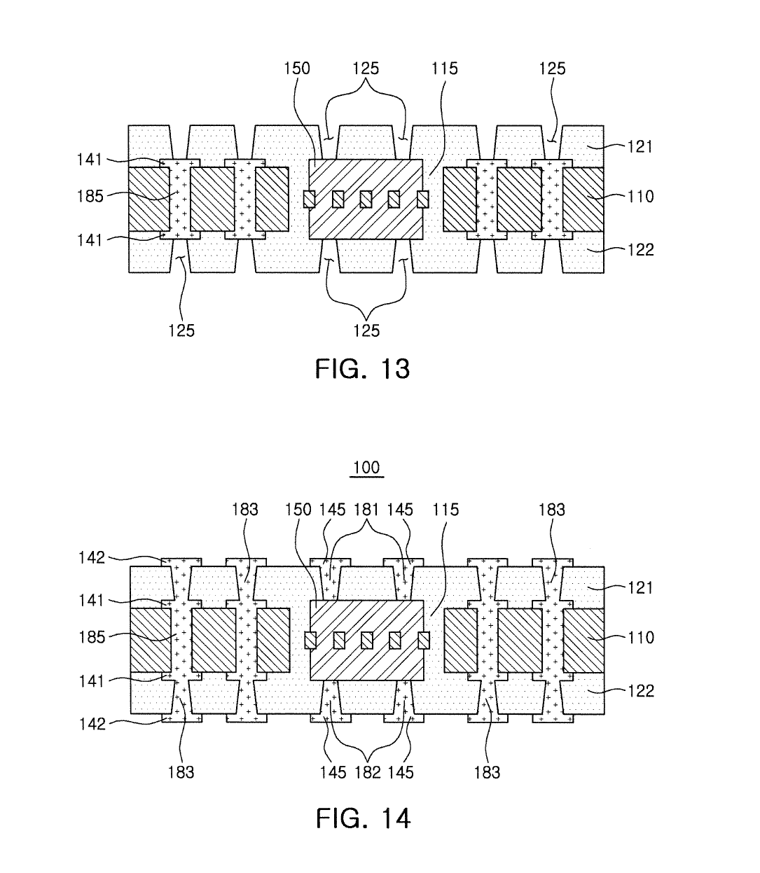

FIGS. 7 through 14 are views sequentially illustrating a manufacturing method of a printed circuit board according to an exemplary embodiment of the present disclosure.

Referring to FIG. 7, first, the cavity 115 may be formed in the core layer 110.

The core layer 110 may have a structure having inner layer circuits 141 formed on an upper surface and a lower surface of the insulating layer and the inner layer circuits 141 formed on the upper surface and the lower surface of the insulating layer may be electrically connected to each other through a core via 185.

The inner layer circuit 141 may be formed by selectively forming an etching resist on a copper layer of a copper clad laminate by a photo-lithography method and applying an etchant on a copper layer region on which the etching resist is not formed, so as to selectively remove the copper layer. The core via 185 for an electrical connection between the inner layer circuits 141 may be formed by forming a through-hole in the core layer 110 and plating the through-hole.

The cavity 115 may be formed by a punch or a blade.

Referring to FIG. 8, a supporting tape 160 may be formed on the lower surface of the core layer 110.

The supporting tape 160 may serve to temporarily fix the heat radiation body 150 inserted into the cavity 115.

Referring to FIG. 9, the heat radiation body 150 may be inserted into the cavity 115.

The heat radiation body 150 inserted into the cavity 115 may be attached to the supporting tape 160 so as to be fixed thereto.

The heat radiation body 150 may include an insulating plate 155, a first metal block 151 formed on an upper surface of the insulating plate 155, and a second metal block 152 formed on a lower surface of the insulating plate 155.

The insulating plate 155 may include a resin insulating material. As the resin insulating material, a thermosetting resin such as an epoxy resin, a thermoplastic resin such as polyimide, or the like may be used, but the resin insulating material is not necessarily limited thereto.

The first metal block 151 or the second metal block 152 may have a rectangular parallelepiped shape, but is not necessarily limited thereto. For example, as long as it may secure a volume and a cross-section area sufficient to improve heat dispersion characteristics, any block shape may be used.

The heat radiation body 150 may include an inner via 158 penetrating through the insulating plate 155.

The first metal block 151 and the second metal block 152 may be connected to each other through the inner via 158.

The first metal block 151, the second metal block 152, and the inner via 158 may be formed of at least one selected from a group consisting of copper (Cu), aluminum (Al), and invar.

Since the heat radiation body 150 having the multilayer structure according to an exemplary embodiment of the present disclosure has an increased volume and cross-section area of the heat dissipating passage, heat dispersion characteristics may be improved and heat of the mounted electronic device may be efficiently dissipated.

Referring to FIG. 10, an insulating layer 121 may be formed on the upper surface of the core layer 110 so as to cover the heat radiation body 150.

As the insulating layer 121 on the upper surface of the core layer 110, a resin insulating layer may be used. As materials of the resin insulating layer, a thermosetting resin such as an epoxy resin, a thermoplastic resin such as polyimide, a resin having a reinforcement material such as glass fiber or inorganic filler impregnated in them, for example, a prepreg may be used. However, the materials of the resin insulating layer are not particularly limited thereto.

By forming the insulating layer 121 on the upper surface of the core layer 110, a space between the cavity 115 and the heat radiation body 150 is filled, whereby the heat radiation body 150 may be fixed to the cavity 115.

Referring to FIG. 11, the supporting tape 160 may be removed.

After the heat radiation body 150 is fixed to the cavity 115 by forming the insulating layer 121 on the upper surface of the core layer 110, the supporting tape 160 may be removed.

As a material of the supporting tape 160, a material that does not leave residues at the time of the removal may be used so as not to influence a process after the removal thereof.

Referring to FIG. 12, an insulating layer 122 may be formed on the lower surface of the core layer 110 so as to cover the heat radiation body 150.

As the insulating layer 121 on the lower surface of the core layer 110, the resin insulating layer may be used, similar to the insulating layer 121 on the upper surface of the core layer 110.

The insulating layers 121 and 122 may be formed on the upper surface and the lower surface of the core layer, so as to bury the heat radiation body 150 in the core layer 110.

Referring to FIG. 13, via holes 125 may be formed in the insulating layers 121 and 122 so as to expose surfaces of the inner layer circuit 141 and the heat radiation body 150.

The via holes 125 may be formed by using a mechanical drill or a laser drill, but is not necessarily limited thereto.

The laser drill may be a CO₂ laser drill or a YAG laser drill, but is not necessarily limited thereto.

Although the case in which the via hole 125 has a tapered shape in which a diameter thereof is decreased in a downward direction has been shown in FIG. 13, the via hole 125 may also have all shapes known in the related art, such as a tapered shape in which a diameter thereof is increased in the downward direction, a circular shape, and the like.

Referring to FIG. 14, a signal via 183 and heat dissipating vias 181 and 182 may be formed by filling the via hole 125 with a conductive material.

The signal via 183, the outer layer circuit 142 on the signal via 183, the heat dissipating vias 181 and 182, and the heat dissipating pads 145 on the heat dissipating vias 181 and 182 may be formed by forming a plating resist having opening parts on the insulating layers 121 and 122 having the via holes 125 formed therein so as to expose the via holes 125 and filling the via holes 125 and the opening parts with the conductive material.

The signal via 183, the outer layer circuit 142, the heat dissipating vias 181 and 182, and the heat dissipating pad 145 may be formed by using a process such as electroplating process, or the like so as to be filled with the conductive material, and as long as conductive material is a metal having excellent electric conductivity, the conductive material may be used without being limited. For example, cooper may be used.

The inner layer circuit 141 and the outer layer circuit 142 may be electrically connected to each other through the signal via 183.

The heat dissipating vias 181 and 182 may be formed so as to be in contact with the heat radiation body 150 and may dissipate heat externally.

The heat dissipating vias 181 and 182 may be formed on both upper and lower sides of the heat radiation body 150.

For example, heat generated from the electronic device mounted on the upper side of the heat radiation body 150 may be transferred to the heat radiation body 150 by the heat dissipating via 181 of the upper side of the heat radiation body 150 and may be transferred to the heat dissipating via 182 of the lower side of the heat radiation body 150, so as to be dissipated externally.

As set forth above, according to exemplary embodiments of the present disclosure, heat generated from the electronic device may be efficiently dissipated and consequently, operation reliability of the electronic device package may be improved.

While exemplary embodiments have been shown and described above, it will be apparent to those skilled in the art that modifications and variations could be made without departing from the scope of the present invention as defined by the appended claims.

What is claimed is:

1. A printed circuit board comprising:
a core layer having a cavity formed therein;
a heat radiation body included in the cavity;
an insulating layer provided on an upper surface and a lower surface of the core layer; and
a heat dissipating via penetrating through the insulating layer to be in contact with the heat radiation body and dissipating heat externally,
wherein the heat radiation body includes an insulating plate, a first metal block provided on an upper surface of the insulating plate, and a second metal block provided on a lower surface of the insulating plate.

2. The printed circuit board of claim 1, wherein the heat radiation body further includes an inner via penetrating through the insulating plate, and
the first metal block and the second metal block are connected to each other through the inner via.

3. The printed circuit board of claim 1, wherein the first metal block or the second metal block has a rectangular parallelepiped shape.

4. The printed circuit board of claim 1, wherein the first metal block or the second metal block includes a plurality of blocks.

5. The printed circuit board of claim 1, wherein the first metal block and the second metal block have different shapes.

6. The printed circuit board of claim 1, wherein the heat dissipating via is provided on an upper side and a lower side of the heat radiation body.

7. The printed circuit board of claim 1, wherein the first metal block and the second metal block include at least one selected from the group consisting of copper (Cu), aluminum (Al), and invar.

8. A method of manufacturing a printed circuit board, the method comprising:
forming a cavity in a core layer;
inserting a heat radiation body into the cavity;
forming an insulating layer on an upper surface and a lower surface of the core layer; and
forming a heat dissipating via penetrating through the insulating layer to be in contact with the heat radiation body,
wherein the heat radiation body includes an insulating plate, a first metal block formed on an upper surface of the insulating plate, and a second metal block formed on a lower surface of the insulating plate.

9. The method of claim 8, wherein the inserting of the heat radiation body into the cavity includes:
disposing supporting tape on the lower surface of the core layer; and
attaching the supporting tape to the heat radiation body.

10. The method of claim 9, further comprising removing the supporting tape after the heat radiation body attached to the supporting tape is fixed to the insulating layer.

11. The method of claim 8, wherein the forming of the heat dissipating via includes:
exposing the heat radiation body by forming a via hole in the insulating layer; and
filling the via hole with a conductive material using a plating process.

12. The method of claim 8, wherein the heat radiation body further includes an inner via penetrating through the insulating plate, and
the first metal block and the second metal block are connected to each other through the inner via.

13. The method of claim 8, wherein the first metal block or the second metal block has a rectangular parallelepiped shape.

14. The method of claim 8, wherein the first metal block or the second metal block includes a plurality of blocks.

15. The method of claim 8, wherein the first metal block and the second metal block have different shapes.

16. The method of claim 8, wherein the heat dissipating via is formed on an upper side and a lower side of the heat radiation body.
